(19) United States
(12) Patent Application Publication
(10) Pub. No.: US 2025/0287728 A1
(43) Pub. Date: Sep. 11, 2025

(54) METHODS FOR FABRICATING QUANTUM DOT OPTOELECTRONIC DEVICES

(71) Applicant: Wisconsin Alumni Research Foundation, Madison, WI (US)

(72) Inventors: Luke J. Mawst, Sun Prairie, WI (US); Chirag Gupta, Middleton, WI (US); Cheng Liu, Madison, WI (US); Padma Gopalan, Madison, WI (US); Nikhil Pokharel, Madison, WI (US); Shubhra Shweta Pasayat, Middleton, WI (US)

(21) Appl. No.: 18/597,232

(22) Filed: Mar. 6, 2024

(51) Int. Cl. H01L 33/00; H01L 33/06; H01L 33/32

(52) U.S. Cl. CPC H10H 20/0137; H10H 20/812; H10H 20/825; H10H 20/0362

(57) ABSTRACT

The present disclosure provides methods for fabricating quantum dot (QD) optoelectronic devices, e.g., light emitting diodes (LEDs) and laser diodes (LDs). The QDs of the optoelectronic devices are multilayer heterostructures of alternating quantum barrier layers and quantum well layer(s) composed of, e.g., III-V semiconductors. The present methods employ nanopatterning along with selective area (SA) growth, in situ selective area (SA) etching, or both SA growth and SA etching. The QD optoelectronic devices are also provided.

### REFERENCE TO GOVERNMENT RIGHTS

This invention was made with government support under W911NF-20-1-0185 awarded by the ARMY/ARO. The government has certain rights in the invention.

### BACKGROUND

Compound III/V semiconductors are foundational materials employed for state-of-the-art optoelectronic devices. Planar ultra-thin heterostructure materials, called quantum wells (QWs), are currently the entrenched commercial technology for realizing high performance semiconductor based light emitters, such as light emitting diodes (LEDs) and laser diodes (LDs). Lower dimensional systems, such as Quantum Dots (QDs) have the potential to produce devices surpassing the performance of planar QW structures. As early as the 1980s, theoretical predictions anticipated that ideal QDs, which offer full three-dimensional carrier confinement at the nanoscale and a delta-function density of states, provide many useful properties for semiconductor diode lasers, including ultra-low current density operation and temperature insensitive device performance. The QDs also provide an effective means for controlling and extending the emission wavelength of light emitting devices.

### SUMMARY

Provided are methods for fabricating quantum dot (QD) optoelectronic devices, e.g., light emitting diodes (LEDs) and laser diodes (LDs). The QDs of the optoelectronic devices are multilayer heterostructures of alternating quantum barrier layers and quantum well layer(s) composed of, e.g., III-V semiconductors. The present methods employ nanopatterning along with selective area (SA) growth, in situ selective area (SA) etching, or both SA growth and SA etching, to provide QD optoelectronic devices characterized by one or more advantages: e.g., high density of monodisperse QDs; high radiative efficiency; and extended emission wavelengths. The present methods further enable cost-effective large area processing. As a result, the QD optoelectronic devices may be used in a variety of applications including solid-state lighting, displays, high-density storage, telecommunications, detectors, etc.

In one embodiment, a method for fabricating a quantum dot optoelectronic device comprises forming a patterned mask layer on a base structure, the patterned mask layer having a plurality of openings defined therein, the base structure comprising a multilayer stack and an etch stop layer below the multilayer stack, the multilayer stack comprising a III-V semiconductor quantum well layer between III-V semiconductor quantum barrier layers; selectively growing, via metalorganic vapor phase epitaxy (MOVPE), a plurality of etch mask layers in respective openings of the plurality of openings of the patterned mask layer; and selectively removing, via in situ etching, material of the base structure not protected by each etch mask layer of the plurality of etch mask layers until the etch stop layer is exposed and a plurality of quantum is formed in the base structure, each quantum dot comprising the multilayer stack and a respective etch mask layer over the multilayer stack.

In another embodiment, a method for fabricating a quantum dot optoelectronic device comprises forming a patterned mask layer on a base structure, the patterned mask layer having a plurality of openings defined therein, the base structure comprising an etch stop layer and a release layer between the patterned mask layer and etch stop layer; removing, via in situ etching, material of the release layer exposed through each opening of the plurality of openings of the patterned mask layer until the etch stop layer is exposed, thereby forming an etched release layer; selectively growing, via MOVPE a plurality of quantum dots in respective openings of the plurality of openings of the patterned mask layer and the etched release layer, each quantum dot comprising a III-V semiconductor quantum well layer between III-V semiconductor quantum barrier layers; selectively growing, via MOVPE, a plurality of etch mask layers on respective quantum dots in respective openings of the plurality of openings of the patterned mask layer and the etched release layer; and removing, via in situ etching, the etched release layer and the patterned mask layer.

In another embodiment, a method for fabricating a quantum dot optoelectronic device comprises forming a patterned mask layer on a base structure, the patterned mask layer having a plurality of openings defined therein; selectively growing, via MOVPE, a plurality of nanopyramid quantum dots in respective openings of the plurality of openings of the patterned mask layer, each nanopyramid quantum dot comprising a III-V semiconductor quantum well layer between III-V semiconductor quantum barrier layers; and removing the patterned mask layer.

Quantum dot optoelectronic devices are also provided. In an embodiment, a quantum dot optoelectronic device comprises a base structure; an active layer on the base structure, the active layer comprising a plurality of quantum dots, each quantum dot comprising a III-V semiconductor quantum well layer between III-V semiconductor quantum barrier layers, wherein each quantum dot has a nanopyramid shape, each quantum dot is between an underlying etch stop layer and overlying etch mask layers, or both

Other principal features and advantages of the disclosure will become apparent to those skilled in the art upon review of the following drawings, the detailed description, and the appended claims.

### BRIEF DESCRIPTION OF THE DRAWINGS

Illustrative embodiments of the disclosure will hereafter be described with reference to the accompanying drawings.

FIG. 1A is a schematic illustration of an embodiment of the present methods for fabricating QD optoelectronic devices based on nanopatterning and selective area growth.

FIG. 1B is a variation of the method of FIG. 1A. FIG. 1C is another variation of the method of FIG. 1A.

FIG. 2A is a schematic illustration of an embodiment of the present methods for fabricating QD optoelectronic devices based on nanopatterning, selective area growth, and in situ selective area etching. FIG. 2B is a variation of the method of FIG. 2A.

FIG. 3 depicts an illustrative QD optoelectronic device (a QD laser) that may be fabricated using the present methods.

FIG. 4A shows a schematic representation of process flow for QD formation by BCP lithography and subsequent MOCVD selective area epitaxy (SAE) on a GaN on patterned sapphire substrate (PSS). The top images show a three-dimensional (3D) view and the bottom images show corresponding cross-sectional views. Top-view SEM images of some of the structures in the process flow are shown in FIGS. 4B, 4C, and 4D.

FIG. 5A shows top-view SEM images of QDs with different pattern transfer CF₄ RIE time; isolated and faceted QDs were achieved from 29 sec and 31 sec etched samples, while merged QDs were observed for longer etched samples. FIG. 5B shows a schematic of epitaxial structure grown on GaN on PSS substrate. Thicknesses were calibrated on planar templates.

FIG. 6A shows a SEM image of as-grown QDs; inset: QD size distribution. FIG. 6B shows QD density from existing fabrication techniques as compared to the present methods.

FIGS. 7A-7C show top views of SEM images and schematics of QD geometry for different growth stages at (FIG. 7A) 300 sec, (FIG. 7B) 600 sec, and (FIG. 7C) 1000 sec.

FIG. 8 shows a cross-sectional HAADF TEM image of 1× InGaN/GaN QDs showing nanopyramid structure with InGaN grown on semi-polar planes.

FIGS. 9A-9B show room temperature PL spectra for (FIG. 9A) planar template and (FIG. 9B) BCP patterned template at 695° C. and 703° C.

FIG. 10A shows PL spectra for QDs grown at 703° C. before and after SiNₓ removal. FIG. 10B shows PL spectra for QDs with different numbers of InGaN/GaN layers.

FIG. 11A shows RT (dash) and LT (77K: solid) PL spectra for 3× InGaN/GaN QD and QW. FIG. 11B shows temperature-dependent integrated PL intensity and wavelength (nm) for 3× InGaN/GaN QD. Dashed lines represent fitting curve based on Varshni's model with E(0), α and β of 2.578 eV, 0.24 meV/K and 4.13×10⁻⁴ K; and Arrhenius equation with E₁, E₂, A₁ and A₂ of 17 meV, 100.2 meV, 0.84 and 6.55. FIG. 11C shows temperature-dependent integrated PL intensity and wavelength (nm) for 3× InGaN/GaN QW.

FIGS. 12A-12B show SEM images taken at various stages of methods similar to the method of FIG. 2A. Specifically, FIG. 12A is an SEM image taken after selectively growing AlGaN etch mask layers within openings of a patterned mask layer. FIG. 12B is an SEM image after ex situ removal of the patterned mask layer via buffered oxide etchants (BOE).

FIGS. 13A-13B show SEM images taken at various stages of a method similar to the method of FIG. 2A. Specifically, FIG. 13A is a top-view SEM image after selectively in situ etching to remove base structure material not protected by overlying etch mask layers to provide a plurality of QDs. FIG. 13B is the 30° tilted view.

FIG. 14A shows photoluminescence spectra (measured at room temperature and an excitation wavelength of 405 nm) from the fabricated QD optoelectronic device made using a method similar to the method of FIG. 2A, before and after cap layer growth. FIG. 14B shows photoluminescence spectra from the fabricated QD optoelectronic device (after cap layer growth) and a comparative optoelectronic device in which the electroluminescent layer is planar, rather than comprising QDs.

### DETAILED DESCRIPTION

The present disclosure provides various methods of fabricating quantum dot (QD) optoelectronic devices.

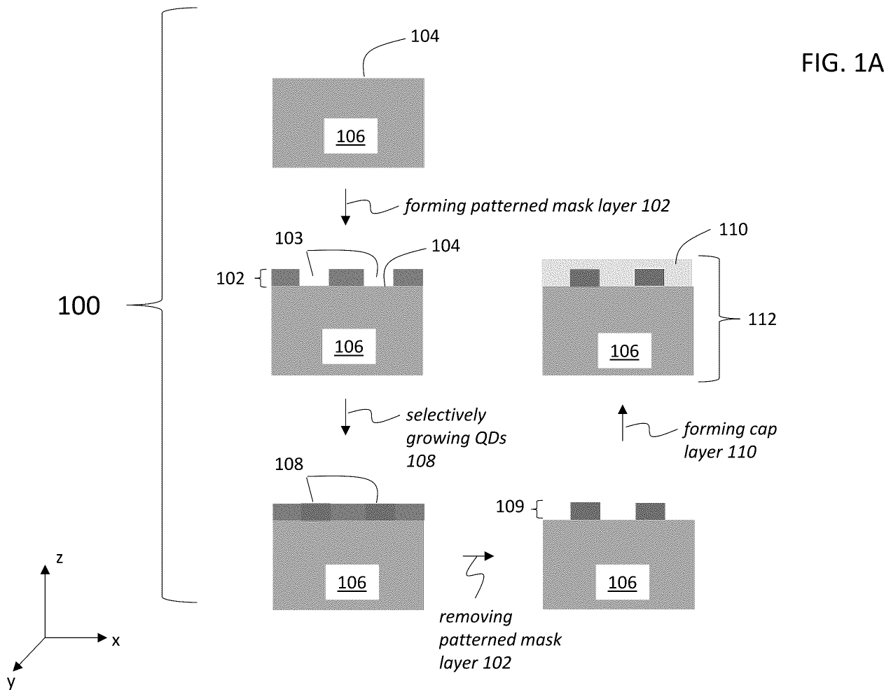

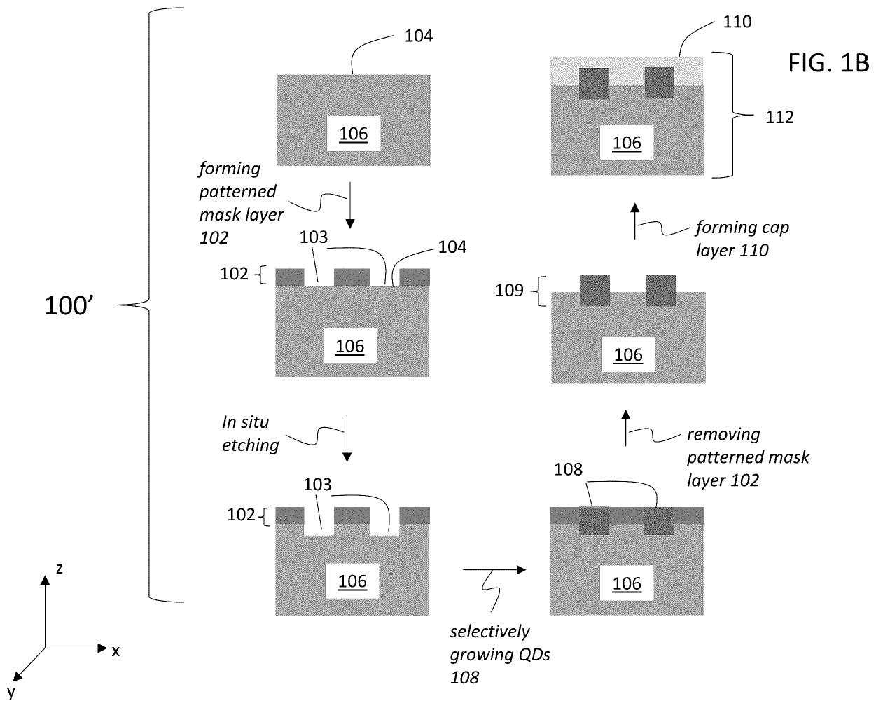

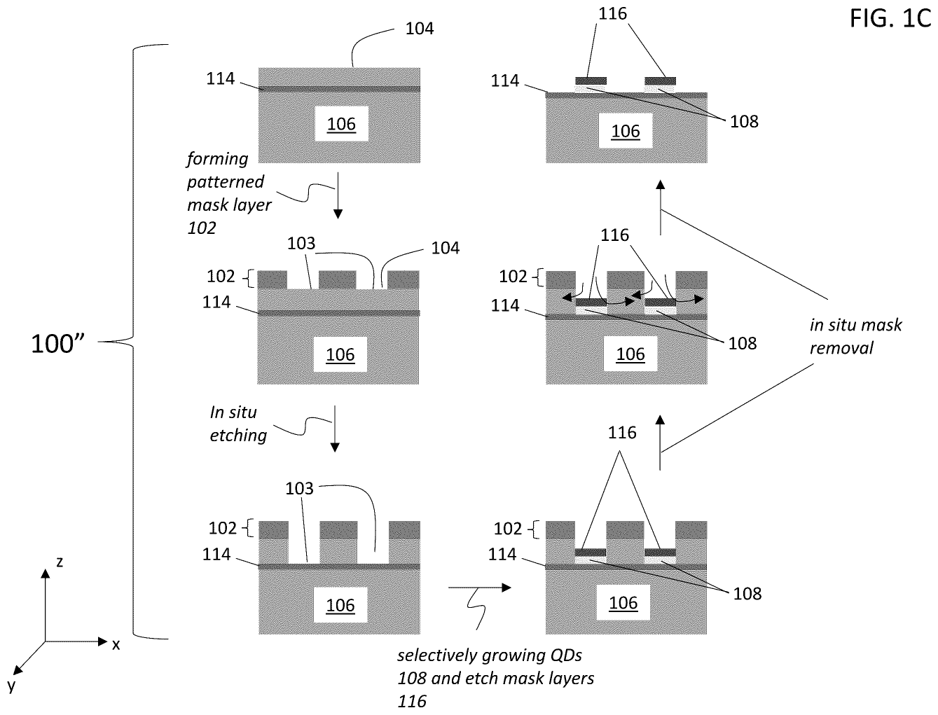

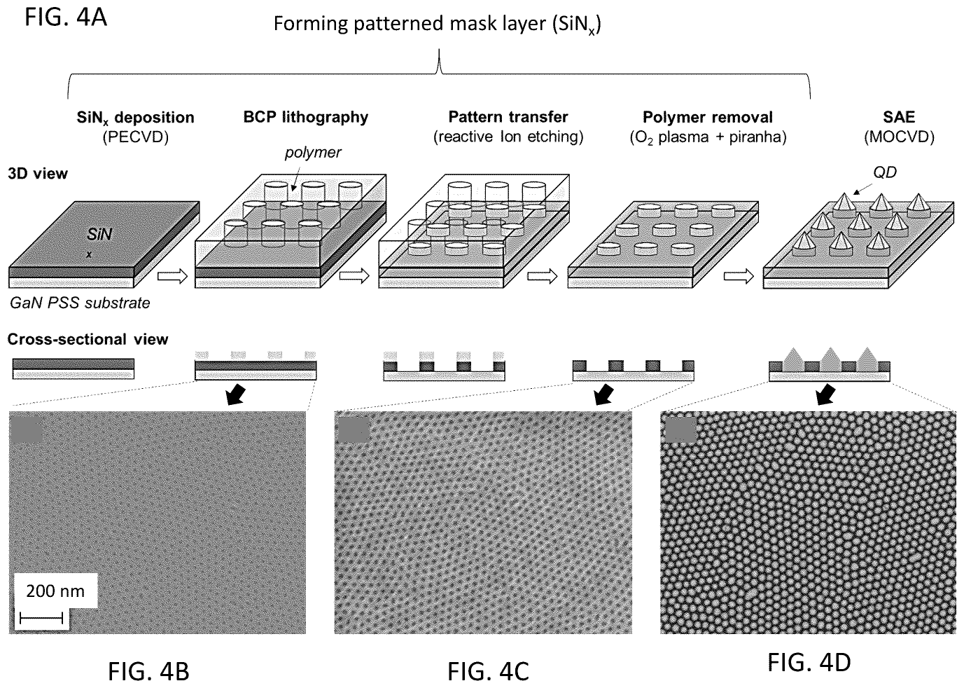

An illustrative method 100 of fabricating a QD optoelectronic device 112 is shown in FIG. 1A. The method 100 comprises forming a patterned mask layer 102 having a plurality of openings 103 defined therein. The patterned mask layer 102 may be formed via block copolymer (BCP) lithography. BCP lithography may be carried out by depositing a mask layer on a surface 104 of a base structure 106 (e.g., via plasma enhanced chemical vapor deposition (PECVD)); applying a BCP layer on a surface of the mask layer, wherein components of the BCP layer self-organize according to a pattern (e.g., polymer stripes, polymer cylinders, polymer spheres, etc. embedded within a polymer matrix); transferring the pattern to the mask layer (e.g., via reactive ion etching (RIE)) to expose the surface 104 of the base structure 106 through the openings 103; and removing the BCP layer from the patterned mask layer 102. These steps for forming a patterned mask layer are illustrated in the images of FIG. 4A labeled with a bracket. BCP lithography is further described in the following references, each of which is incorporated by reference in its entirety: L. J. Mawst, et al., IEEE Journal of Quantum Electronics 58, 4, 1 (2022); H. Kim, et al., Journal of Crystal Growth 465, 48 (2017); H. Kim, et al., Semiconductor Science and Technology 34, 2, 025012 (2019); and G. Liu, et al., Nanoscale Research Letters 6, 1 (2011); U.S. Pat. Nos. 9,587,136; 9,115,255; and 8,999,623.

With reference back to FIG. 1A, the method 100 further comprises selectively growing quantum dots (QDs) 108 within respective openings 103 of the patterned mask layer 102. The selective growth may be carried out via metalorganic vapor phase epitaxy (MOVPE). The term MOVPE may be used interchangeably with metalorganic chemical vapor deposition (MOCVD). Selective growth using these techniques may be referred to using phrases such as “selective area growth” and “selective area epitaxy.” The selective nature of such growth techniques relates to epitaxial growth only on crystalline surfaces (i.e., the surface 104 of the base structure 106 exposed through the openings 103) versus growth on the patterned mask layer 102. The plurality of QDs 108 formed within the openings 103 forms an electroluminescent, active layer 109 of the optoelectronic device 112. The method 100 further comprises removing the patterned mask layer 102, e.g., via etching (e.g., wet chemical etching or RIE) which may be accomplished outside of the MOVPE reactor (i.e., ex situ). The method 100 may further comprise forming a cap layer 110 on the active layer 109 comprising the plurality of QDs 108 to provide the optoelectronic device 112.

The base structure 106 on which the patterned mask layer 102 is formed may assume various configurations depending upon the desired optoelectronic device. For example, the base structure 106 may comprise a substrate and one or more additional layers thereon, the material selection and arrangement of which also depends upon the desired optoelectronic device. However, suitable materials for the one or more additional layers include III-V semiconductors. By III-V semiconductors, it is meant various alloy compositions of one or more Group III elements (e.g., Al, Ga, In) and one or more Group V elements (e.g., N, P, As, Sb). It is understood that the relative amounts of each selected Group III and Group V element in the III-V semiconductor may vary, depending upon the desired optoelectronic device and its optical properties. Any substrate compatible with III-V semiconductors may be used, e.g., sapphire (a-sapphire, m-sapphire, c-sapphire), silicon (Si(111), Si(100)), silicon carbide (SiC), bulk III-V substrate (c-plane, semi-polar, or non-polar GaN; c-plane, semi-polar, or non-polar AlN; InP (001); InP (111); GaAs (001); GaAs (111); GaP (001); GaP (111)), etc. As further described below, variations on the basic fabrication method 100 illustrated in FIG. 1A also influence the particular configuration of the base structure 106, including the use of and relative arrangement of additional layers above the substrate.

As noted above, the patterned mask layer 102 is formed from a previously deposited mask layer. A variety of dielectric materials may be used for the mask layer, e.g., silicon nitride (SiNₓ), silicon oxide (SiO₂), etc. The openings 103 defined in the patterned mask layer 102 may assume various dimensions, shapes, and arrangements, depending upon the desired optoelectronic device and characteristics of the patterning process (e.g., BCP lithography). Regarding dimensions, however, the openings 103 are nanoscale meaning that the x, y, z dimensions of the openings 103 are nanoscale, e.g., 100 nm or less, 75 nm or less, 50 nm or less, or 30 nm or less. (See the xyz axes labeled in FIG. 1A.) This includes having dimensions which are in a range of from 10 nm to 50 nm, from 15 nm to 50 nm, and from 20 nm to 30 nm. Circular openings 103 may be characterized as by a diameter d taken within the xy plane; the diameter d may be within any of the nanoscale ranges described above. The height of the openings is taken along the z axis (this dimension also corresponds to the thickness of the patterned mask layer 102). The nanoscale dimensions of the openings 103 ensure quantum confinement of QDs selectively grown within patterned mask layer openings 103 as described above or, as further described below, of QDs defined by selectively in situ etching around patterned mask layer openings 103.

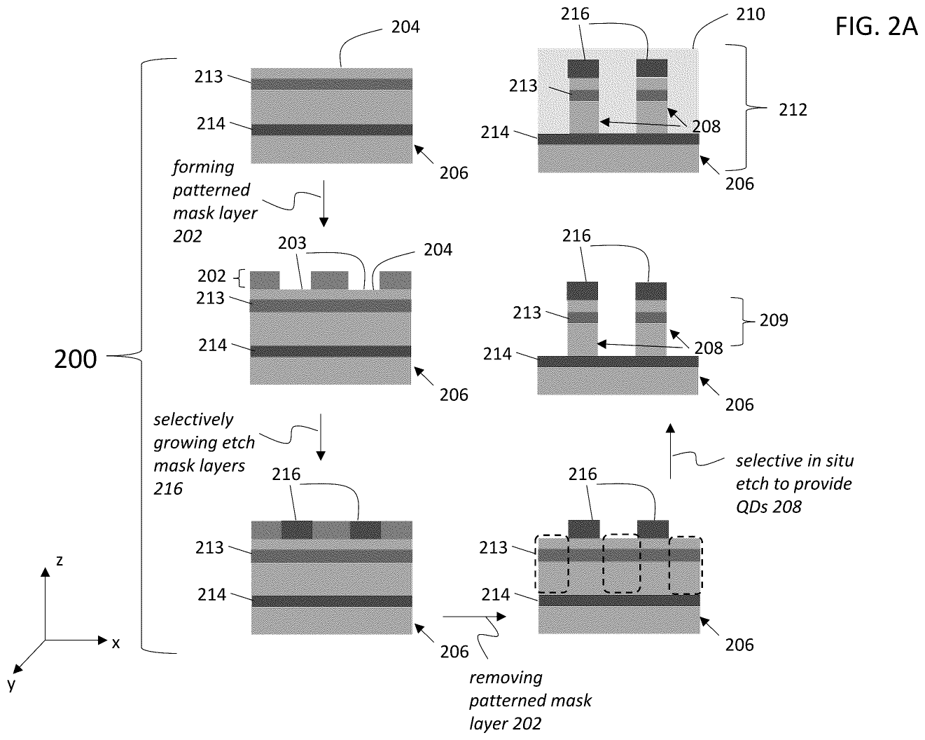

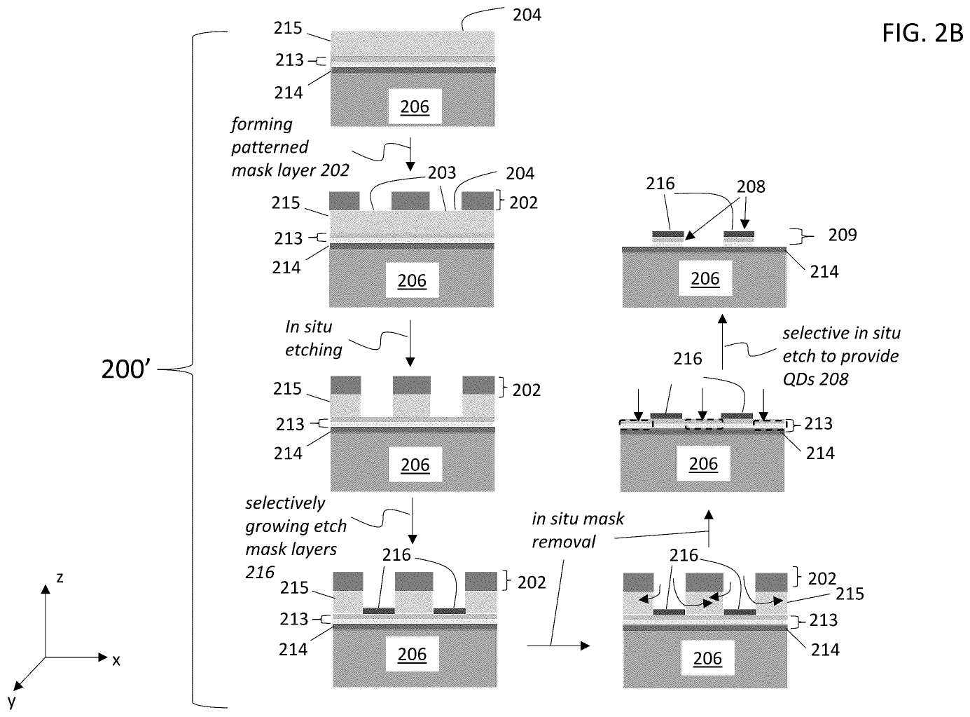

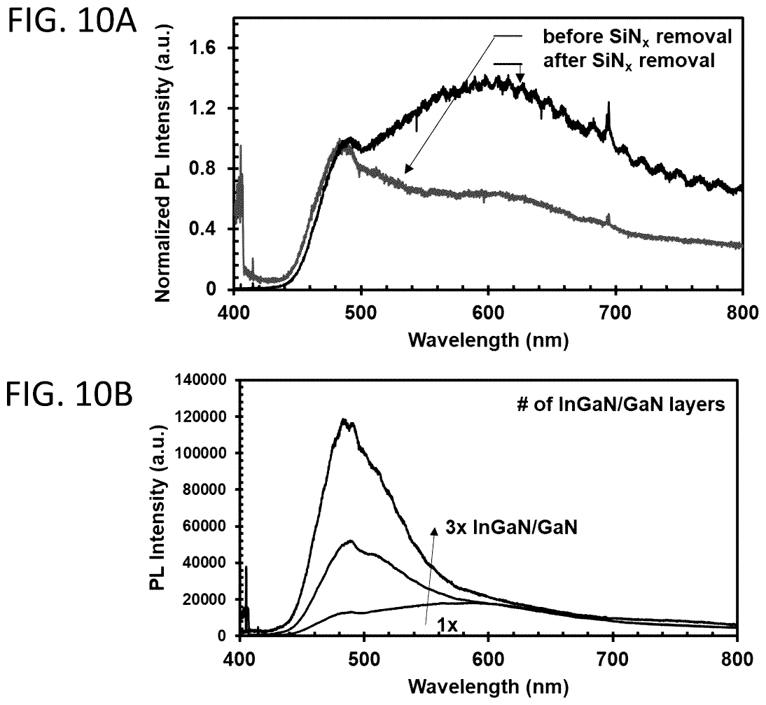

As illustrated in FIG. 1A and noted above, in embodiments, the QDs 108 are selectively grown within the openings 103 of the patterned mask layer 102. As illustrated in FIG. 2A and further described below, in other embodiments, QDs are formed by selectively in situ etching around patterned mask layer openings. However, regardless of the specific fabrication method used, the QDs of the present optoelectronic devices are multilayer structures (i.e., heterostructures) comprising a quantum well (QW) sublayer sandwiched between quantum barrier (QB) sublayers. As noted above, the QW and QB sublayers may be composed of III-V semiconductors; a QW sublayer is composed of a lower bandgap III-V semiconductor while a QB sublayer is composed of a higher bandgap III-V semiconductor. Otherwise, the specific selection of III-V semiconductors for the QW and QB sublayers depends upon the desired optoelectronic device and its optical properties, e.g., wavelength of light emitted by the plurality of QDs. Illustrative QW/QB combinations include, e.g., InGaAs (QW)/GaAs (QB); InGaAs (QW)/InGaAs (QB); InGaAs (QW)/AlInAs (QB); InGaAs (QW)/GaAsP (QB); InGaAsP (QW)/InGaAsP (QB); InGaN (QW)/GaN (QB); InGaN (QW)/InGaN (QB); InGaN (QW)/AlGaN (QB); GaN (QW)/AlGaN (QB); AlInGaN (QW)/GaN (QB); AlInGaN (QW)/AlGaN (QB); and AlInGaN (QW)/AlInGaN (QB), etc. The QDs may comprise multiple QW sublayers, each sandwiched between QB sublayers. The number of sublayers in the multilayer stack constituting the QDs may be adjusted as desired, including to increase intensity of light emitted by the QDs (see FIG. 10B).

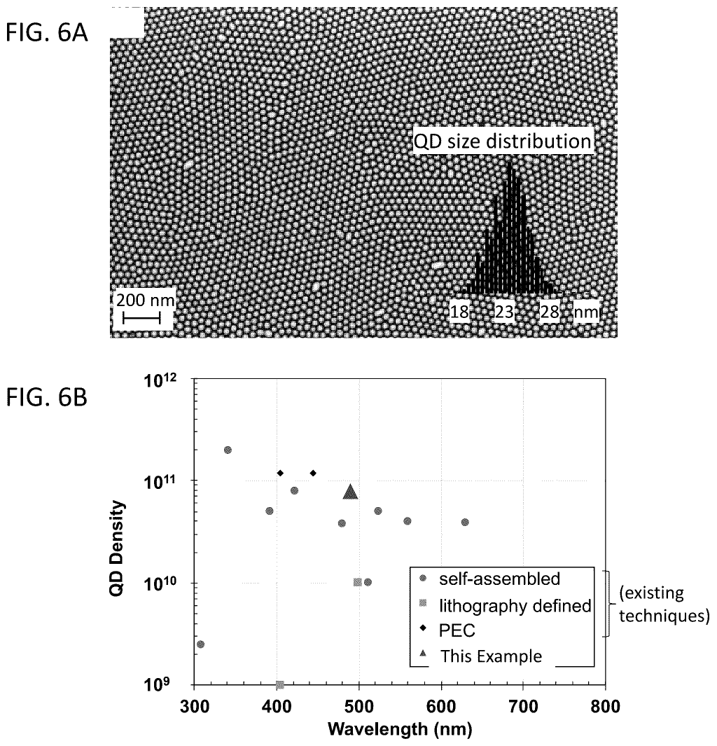

As noted above, the dimensions of the QDs of the present optoelectronic devices are nanoscale to ensure quantum confinement. Thus, any of the dimensions described above with respect to the patterned mask layer openings 103 apply to the QDs. This includes the diameter d of the patterned mask layer openings 103 corresponding to the diameter of the QDs. The thickness of the individual sublayers of the QDs may be adjusted as desired, e.g., to tune optical properties. However, the overall height of the QDs (as measured along the z axis) is also nanoscale as described above. The patterned mask layer openings, and thus the QDs defined thereby, are characterized by a high monodispersity, i.e., narrow size distributions. (See FIG. 6A.) This includes the QDs having a monomodal size distribution (measured as described in the Example, below) having a standard deviation of no more than 15% of an average of the monomodal size distribution (i.e., average QD size), no more than 12% of the average QD size, or no more than 10% of the average QD size. Similarly, the patterned mask layer openings, and thus the QDs, are characterized by a high density, i.e., large number of QDs within the electroluminescent layer. This includes a QD density (measured as described in the Example, below) of at least 5×10¹⁰ cm⁻², at least 7×10¹⁰ cm⁻², and at least 1011 cm⁻².

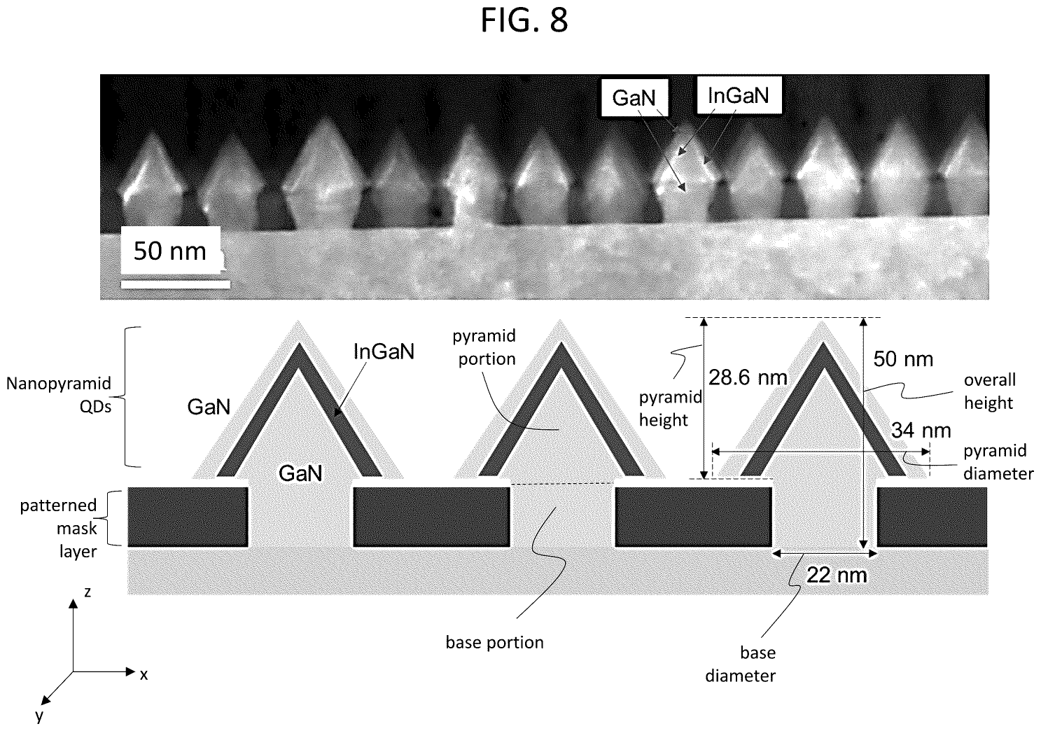

Regarding the shape of the QDs of the present optoelectronic devices, in embodiments, the shape generally corresponds to that of patterned mask layer openings which define the QDs (either by selective growth within, or selective in situ etching around, the patterned mask layer openings). However, in embodiments, the QDs have a nanopyramid shape. Such QDs may be referred to as “nanopyramid QDs” and are characterized by having at least some facets (e.g., three or more) that meet together at a point above a base surface as in a pyramid. Schematic xy cross-sectional views of nanopyramid QDs are shown in the bottom half of FIG. 8, while HAADF TEM images of fabricated nanopyramid QDs are shown in the top half of FIG. 8. As shown in FIG. 8, a nanopyramid QD may be composed of a base portion positioned within an opening of a patterned mask layer and a pyramid portion extending from the base portion and above the opening. Dimensions of a nanopyramid QD include those labeled in FIG. 8: a base diameter, a pyramid diameter (or width); a pyramid height; and an overall height. The values of each of these dimensions may be within any of those described above with respect to the dimensions of the openings 103 of the patterned mask layer 102.

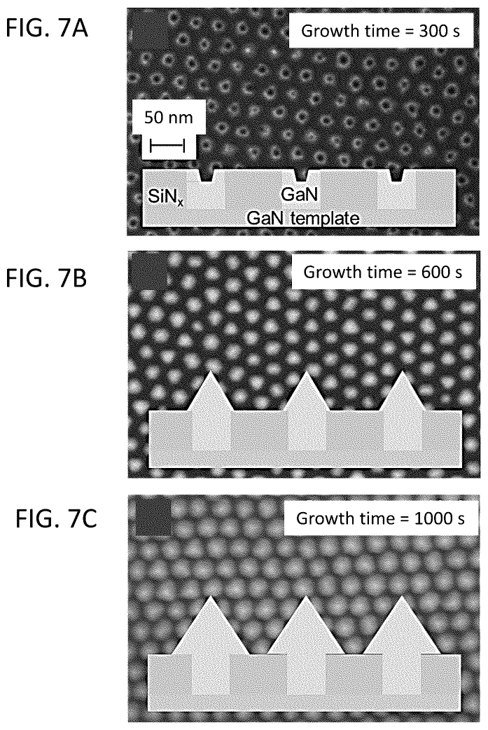

The ability to achieve nanopyramid QDs was a serendipitous result of tuning certain parameters in the selective growth of the QDs via MOVPE. The selective growth process of nanopyramid QDs via MOVPE is illustrated in FIGS. 7A-7C and further described in the Example, below. It was found that nanopyramid QDs could be formed only by using certain combinations of growth rate, temperature, pressure, carrier gas, and thickness of a patterned mask layer. The specific values of these parameters depend upon the composition of the QDs and the surface of the base structure on which they are grown, but illustrative values are provided in the Example, below. For example, in embodiments, the following values are used to ensure growth of nanopyramid QDs: temperature in a range of between 600° C. and 1000° C.; pressure in a range of between 50 mbar and 600 mbar; N₂ carrier gas; patterned mask layer thickness between 5 nm and 50 nm; and growth rate between 0.5 nm/min and 60 nm/min.

Formation of nanopyramid QDs may be confirmed from TEM images such as that shown in FIG. 8. Such images and associated TEM software may also be used to measure dimensions of the QDs as well as their size distribution and density.

Nanopyramid QDs exhibit one or more advantages, e.g., increased surface area (which is useful to increase the intensity of light emission from the present optoelectronic devices); increased incorporation of indium; lower etching rates (which is useful during selective in situ etching steps as described below); and reduced built-in polarization field (which is useful to reduce quantum confined stark effects).

The QDs of the present optoelectronic devices may be further characterized by their crystalline orientation at their upper surfaces (or facets thereof). In embodiments, this crystalline orientation is a semi-polar crystalline orientation. By way of illustration, GaN growth in the {1 0 1̅ 1} semi-polar crystalline orientation (see FIGS. 7A-7C) results in both the subsequently grown InGaN quantum well layer and the subsequently grown upper GaN quantum barrier layer of the QDs in FIG. 8 having this semi-polar crystalline orientation. As described in the Example below, the ability to grow QDs having semi-polar crystalline orientations, even when the QDs are grown from a c-plane surface, is another unique, advantageous feature of the present fabrication methods.

As noted above, MOVPE may be used to grow layers of the present QD optoelectronic devices, including the QDs. Any reactor system suitable for carrying out MOVPE may be used. Layers may be grown by exposing the desired surface to a vapor composition comprising a group III precursor comprising a group III element and a group V precursor comprising a group V element. The vapor composition generally comprises a carrier gas or gas mixture. The exposure takes place under conditions sufficient to form a compound semiconductor from the group III and V precursors via MOVPE. The group III precursors are metalorganic compounds comprising a group III element (e.g., Al, Ga, In). A variety of group III precursors may be used, e.g., trimethyl-, triethyl-, triisopropyl, triisobutyl-group III precursors. Similarly, a variety of group V precursors may be used, e.g., hydrogen pnictides, e.g., ammonia (NH₃). A single type of group III precursor and a single type of group V precursor may be used to form binary III-V semiconductors. Multiple, different types of group III precursors and/or multiple, different types of group V precursors may be used to form various III-V semiconductor alloys.

By “conditions” as that term is used with respect to the formation of the III-V semiconductor via MOVPE refers to parameters such as flow rate of the group III precursor, flow rate of the group V precursor, ratio of the flow rates of the group III and group V precursors, time of exposure to the vapor composition, temperature, type of carrier gas (e.g., N₂, H₂, mixtures thereof), and pressure of the vapor composition. In general, specific values for these parameters depends upon the desired optoelectronic device and its optical properties. Moreover, as noted above, these parameters may be adjusted to ensure growth of nanopyramid QDs. For example, certain of these parameters affect the growth rate of the III-V semiconductor and as described in the Example below, lower growth rates are useful to ensure formation of nanopyramid QDs. Otherwise, illustrative specific values for these parameters are provided in the Example, below.

With reference back to FIG. 1A, the method 100 may further comprise forming the cap layer 110 on the active layer 109 comprising the plurality of QDs 108 to provide the optoelectronic device 112. The cap layer 110 may be composed of a III-V semiconductor grown via MOVPE. In embodiments, the cap layer 110 is formed using a two-step MOVPE growth procedure comprising MOVPE growth of a first cap sublayer and MOVPE growth of a second cap sublayer on the first cap sublayer. The MOVPE growth conditions are different for the two sublayers, including use of a lower temperature, lower pressure, and lower growth rate for the first cap sublayer as compared to the second cap sublayer. In other embodiments, single-step MOVPE growth is sufficient to achieve the cap layer 110.

A variation of the illustrative method 100 of FIG. 1A is shown in FIG. 1B. In this variation (method 100′), an in situ etching step (e.g., via MOCVD) is carried out after forming the patterned mask layer 102 and before selectively the QDs 108. By “in situ” it is meant that the etching occurs in the same reactor used to selectively grow the QDs 108 without opening the reactor to the atmosphere in between these steps. The in situ etching step removes material of the base structure 106 exposed through the openings 103. This is useful to remove surface oxides and any other undesired material from the surface on which the QDs are to be selectively grown. As illustrated in FIG. 1B, the in situ etching step further deepens the openings 103 in which the QDs 108 are selectively grown.

Another variation of the illustrative method 100 of FIG. 1A is shown in FIG. 1C. This variation (method 100″) also includes an in situ etching step as was shown in FIG. 1B. However, in the method 100″, the base structure 106 further comprises an etch stop layer 114. The etch stop layer 114 is composed of a material (which may be a III-V semiconductor) that has an etching rate lower than that of material to be removed in the in situ etching step. For example, if the base structure 106 includes a layer of GaN to be removed in the in situ etching step, the etch stop layer 114 may be composed of AlGaN. As another example, if the base structure 106 includes a layer of InP or InGaAs to be removed in the in situ etching step, the etch stop layer 114 may be composed of AlInAs. In the in situ etching step of method 100″, material of the base structure 106 is removed through the openings 103 until the etch stop layer 114 is exposed. The layer in which the material of the base structure 106 is removed (i.e., the layer between the patterned mask layer 102 and the etch stop layer 114) may be referred to as a release layer.

With continuing reference to FIG. 1C, the QDs 108 are then selectively grown in the openings 103. The method 100″ further comprises an additional step of selectively growing (e.g., via MOVPE) etch mask layers 116 on respective QDs 108. The etch mask layers 116 are also composed of a material (which may be a III-V semiconductor) that has an etching rate lower than that of the material to be removed in a subsequent in situ mask removal step. The etch mask layers 116 can, but need not, have the same composition as that of the etch stop layer 114. For example, etch mask layers 116 and the etch stop layer 114 may both be composed of AlGaN, but having different amounts of Al.

With continuing reference to FIG. 1C, the in situ mask removal step is carried out to remove material laterally surrounding the QDs 108, including lateral portions of base structure 106 (i.e., the etched release layer) and the patterned mask layer 102 thereon. Analogous to FIG. 1B, in the method 100″ of FIG. 1C, by “in situ” it is meant that the respective etching steps occur in the same reactor used in the steps of selectively growing the QDs 108 and selectively growing the etch mask layers 116 without opening up the reactor to the atmosphere in between any of the etching and growth steps. Although not shown in FIG. 1C, the method 100″ may further comprise growing a cap layer on the QDs 108 as described above. As shown in FIG. 1C, the steps of this embodiment result in the QDs 108 having a respective etch mask layer 116 on its uppermost surface.

As noted above, in embodiments, the QDs of the present optoelectronic devices are formed by selective in situ etching of a base structure (versus selective growth on a base structure as described above). An illustrative embodiment of such a method 200 is shown in FIG. 2A. Like method 100, method 200 also comprises forming a patterned mask layer 202 (e.g., via BCP lithography) having a plurality of openings 203 defined therein. However, in the method 200, a base structure 206 further comprises an etch stop layer 214 and a sublayer (or a multilayer stack comprising the sublayer) from which a plurality of QDs 208 is formed in a subsequent selective in situ etching step (e.g., via MOCVD). In other words, element 213 of FIG. 2A may be a QW or QB sublayer or a multilayer stack of QW and QB sublayers. The etch stop layer 214 is composed of a material (which may be a III-V semiconductor) that has an etching rate lower than that of material to be removed in the subsequent in situ etching step. As also described above, the QW and QB sublayers may be composed of various III-V semiconductors; multiple QW sublayers may be used, each sandwiched between QB sublayers; and the number of sublayers may be adjusted as desired.

With continuing reference to FIG. 2A, the method 200 further comprises selectively growing (e.g., via MOVPE) etch mask layers 216 (rather than quantum dots as in FIGS. 1A-1C) within respective openings 203 of the patterned mask layer 202. The etch mask layers 216 are also composed of a material (which may be a III-V semiconductor) that has an etching rate lower than that of the material to be removed in the subsequent selective in situ etching step. The etch mask layers 216 can, but need not, have the same composition as that of the etch stop layer 214. The method 200 further comprises removing the patterned mask layer 202 (e.g., via ex situ etching). The method 200 further comprises the selective in situ etching step in which material of the base structure 206 that is not protected by the overlying etch mask layers 216 is removed until the etch stop layer 214 is exposed. This in situ etching step is a vertical etch that removes material of the base structure 206 (indicated by dotted lines) laterally surrounding other material of the base structure 206 disposed directly underneath the etch mask layers 216. The selective nature of this in situ etching step relates to the etching only of material not protected by the etch mask layers 216 and the etch stop layer 214. This selective in situ etching step provides a plurality of QDs 208, forming an electroluminescent, active layer 209 of an optoelectronic device 212. The QDs may have any combination of the characteristics described above with respect to the plurality of QDs 108. However, as shown in FIG. 2A, the steps of this embodiment result in the QDs 208 having a respective etch mask layer 216 on its uppermost surface. The method 200 may further comprise forming a cap layer 210 to provide the optoelectronic device 212. In the method 200, by “in situ” it is meant that the etching occurs in the same reactor used to form the cap layer 210 without opening the reactor to the atmosphere in between these steps.

Further regarding the etch mask layers 216 (as well as the etch mask layers 116), MOVPE growth conditions may be selected to provide these layers having a nanopyramid shape as described above with respect to QDs 108. This is useful, at least in part, as the etch rate of a nanopyramid structure is lower than that of a corresponding planar structure.

A variation of the illustrative method 200 of FIG. 2A is shown in FIG. 2B. In this variation (method 200′), the base structure 206 further comprises a release layer 215 above a multilayer stack 213. The release layer 215 is composed of a material (which may be a III-V semiconductor) that has an etching rate higher than material on which the release layer 215 is formed. The material on which the release layer 215 is formed may be a layer (e.g., a QB layer) of the multilayer stack 213. The method 200′ further comprises an additional in situ etching step (e.g., via MOCVD) carried out after forming the patterned mask layer 202 and before selectively growing the etch mask layers 216. This in situ etching step removes material of the base structure 206 (including material of the release layer 215) exposed through the openings 203 until a surface of the multilayer stack 213 is exposed. The method 200′ further comprises selectively growing the etch mask layers 216 within respective openings 203 of the patterned mask layer 202 (and corresponding openings in the etched release layer 215).

With continued reference to FIG. 2B, the method 200′ further comprises an in situ mask removal step in which material laterally surrounding the etch mask layers 216, including lateral portions of base structure 206 (specifically, the etched release layer 215) and the patterned mask layer 202 thereon are removed. The method 200′ further comprises a selective in situ etching step in which material of the base structure 206 not protected by the overlying etch mask layers 216 (indicated by dotted lines) is removed until the etch stop layer 214 is exposed, thereby providing the plurality of QDs 208.

The materials of the base structure 206, the multilayer stack 213, the etch stop layer 214, the release layer 215, and the etch mask layers 216 have been generally described above. However, the materials may be selected such that the relative etching rates arranged from highest etching rate to lowest etching rate are as follows: release layer 215>material of the base structure 206 on which the release layer 215 is formed (which may be an uppermost sublayer of the multilayer stack 213)>multilayer stack 213 (or other sublayers thereof)>etch stop layer 214˜etch mask layers 216.

Analogous to FIG. 1B, in the method 200′ of FIG. 2B, by “in situ” it is meant that the respective etching steps occur in the same reactor used in the steps of selectively growing the etch mask layers 216 without opening up the reactor to the atmosphere in between any of the etching and growth steps. Although not shown in FIG. 2B, the method 200′ may further comprise growing a cap layer on the QDs 208 as described above. As shown in FIG. 2B, the steps of this embodiment result in the QDs 208 having a respective etch mask layer 216 on its uppermost surface.

Regarding the illustrative methods shown in FIGS. 1C and 2B, these methods employ multiple in situ etching steps. Conditions used during the in situ etching steps may be independently adjusted as desired. Regarding conditions, these include the etchant gases that may be used. For example, for III-V semiconductors, CBr₄ may be used. For III-N semiconductors, a combination of H₂ and NH₃ may be used; tert-Butyl chloride may also be used.

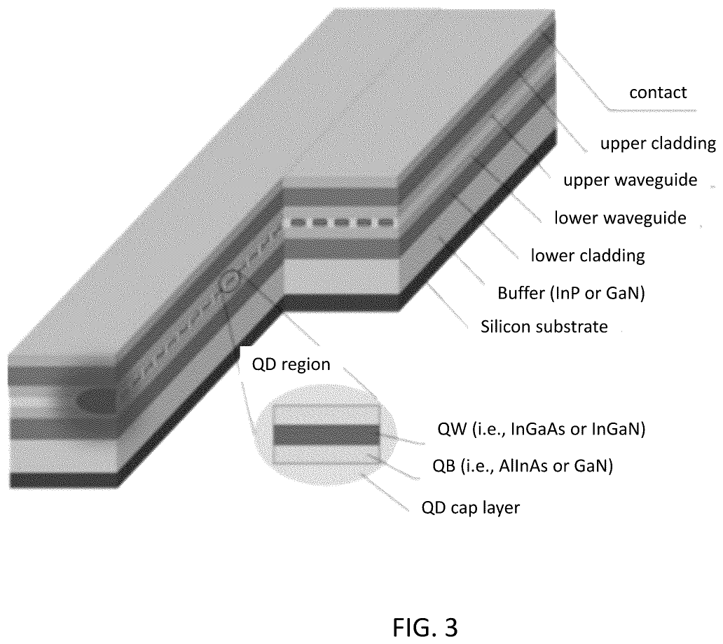

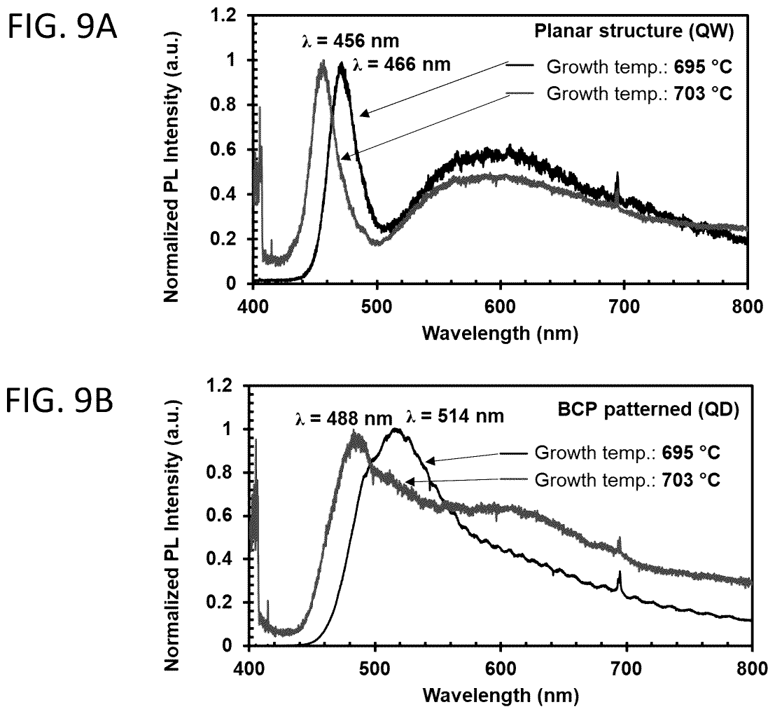

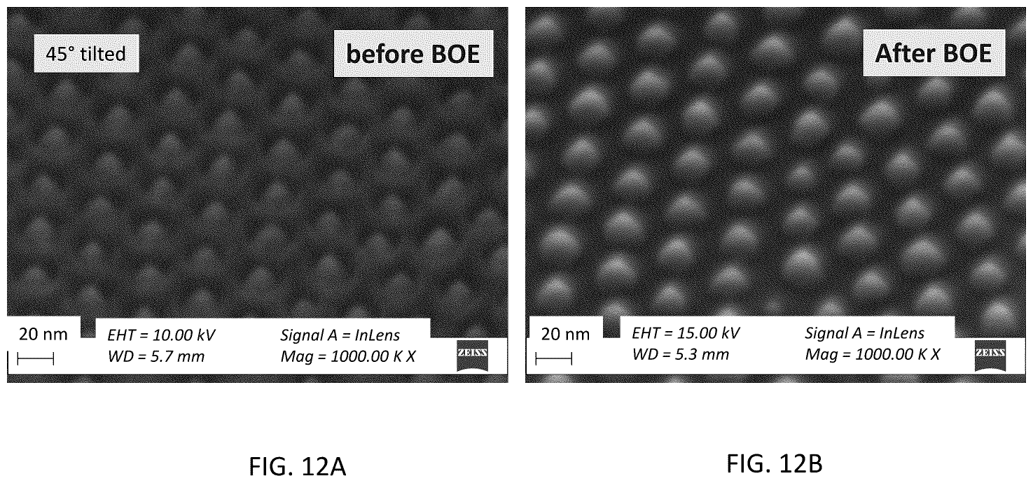

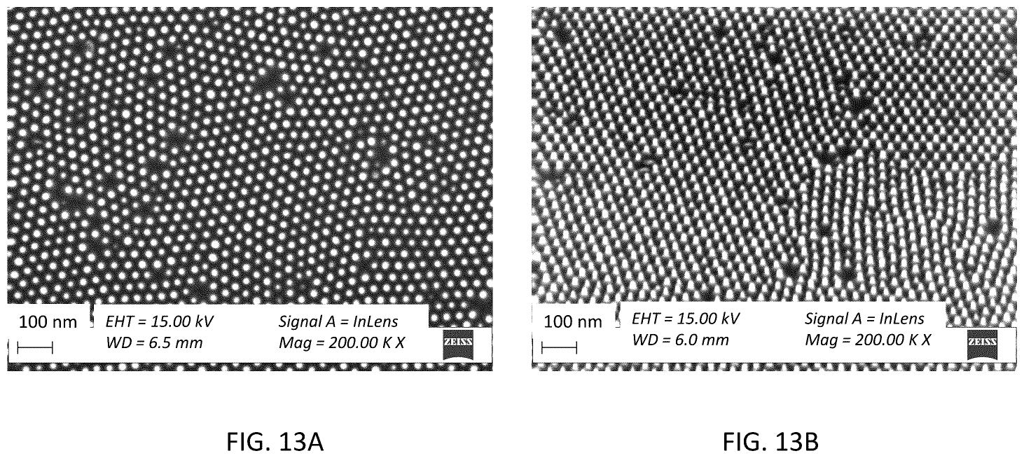

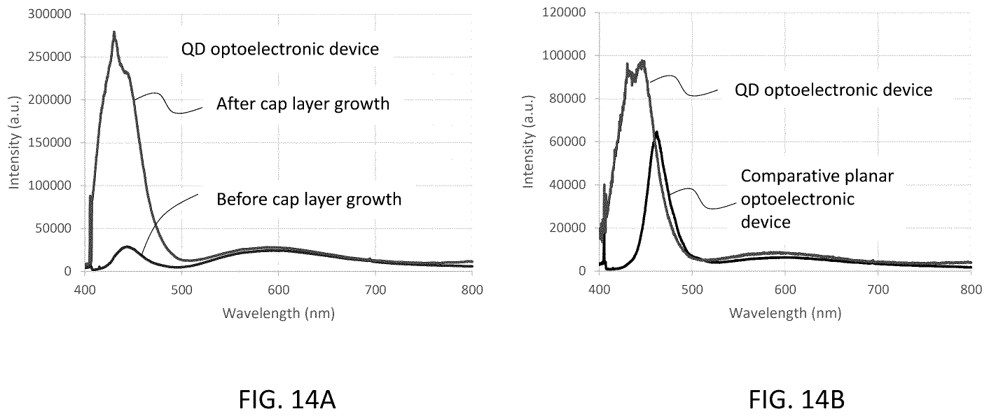

The Example below and FIGS. 4A-4D to 8 describe use of a method similar to method 100 of FIG. 1A to fabricate QD optoelectronic devices comprising nanopyramid QDs. Optical properties of the QD optoelectronic devices are shown in FIGS. 9B to 11A-11C and further described below. Methods similar to method 200′ of FIG. 2A were also used to fabricate QD optoelectronic devices. SEM images taken at various stages of the methods are shown in FIGS. 12A-12B and 13A-13B. Specifically, FIG. 12A is an SEM image taken after selectively growing AlGaN etch mask layers within openings of a patterned mask layer. FIG. 12B is an SEM image after ex situ removal of the patterned mask layer via buffered oxide etchants (BOE). FIG. 13A is a top-view SEM image after selective in situ etching to remove base structure material that is not protected by overlying etched mask layers to provide a plurality of QDs. FIG. 13B is the 30° tilted view. FIG. 14A shows photoluminescence spectra (measured at room temperature and an excitation wavelength of 405 nm) from the fabricated QD optoelectronic device before and after growth of a cap layer. FIG. 14B shows photoluminescence spectra from the fabricated QD optoelectronic device (after cap layer growth) and a comparative optoelectronic device in which the electroluminescent layer is planar, rather than comprising QDs. Significantly, the results show that the photoluminescence of the QD optoelectronic device is higher than that of the comparative optoelectronic device. The QD optoelectronic devices fabricated using any of the present methods are also encompassed by the present disclosure. In general, the QD optoelectronic devices comprise a base structure, an electroluminescent, active layer comprising a plurality of QDs on a surface of the base structure, and generally, a cap layer on the active layer. The configuration of the base structure and the QDs in the QD-containing active layer follow the description provided above. The presence of other material layers in the QD optoelectronic devices (e.g., etch stop layers, etch mask layers, etc.) as well as the relative arrangement of the various material layers depends upon the specific fabrication method used. By way of example, as noted above, in embodiments, bottommost surfaces of the QDs each form an interface with (i.e., is in direct contact with), an underlying etch stop layer; uppermost surfaces of the QDs each form an interface with (i.e., is in direct contact with), an overlying etch mask layer; or both. As also noted above, depending upon the configuration of the base structure (and the desired optoelectronic device) additional material layers may be present, e.g., carrier injection layer(s), carrier collection layer(s), waveguide layer(s), contact layer(s), cladding layer(s), etc. An illustrative QD laser device is shown in FIG. 3. Any of the various material layers of the present QD optoelectronic devices may be doped (p-type or n-type) or undoped as desired.

The present QD optoelectronic devices may be characterized by various optical properties. This includes the wavelength of light emitted therefrom. A broad range of wavelengths may be achieved due to ability of the present methods to form QDs of various sizes and compositions. For example, the wavelength of the light emission may be within the ultraviolet (e.g., from about 200 nm to less than about 400 nm), the visible (e.g., from about 400 nm to less than about 800 nm), or the near infrared portion (from about 800 nm to about 6 μm). These values may refer to peak wavelengths as measured photoluminescence spectra obtained at a particular temperature (e.g., room temperature) and a suitable excitation wavelength as described in the Example, below. The light emitted from the present QD optoelectronic devices is generally highly intense due to the ability of the present methods to form monodisperse, multilayer QDs at high densities. Other optical properties include the full width at half maximum (FWHM) of the light emission and the internal quantum efficiency (IEQ). Regarding FWHM (which may be determined from photoluminescence spectra as described above), these values may be no more than 50 meV, no more than 100 meV, or no more than 300 meV. This includes a range between any of these values and from 50 meV to 1000 meV, from 100 meV to 750 meV, and from 300 meV to 500 me V. Regarding IQE (which may be determined using the techniques described in the Example below), these values may be at least 50%, at least 60%, or at least 70%. This includes a range between any of these values and from 50% to 99%, from 60% to 90%, and from 65% to 80%.

Both the physical structures and the optical properties of the present QD optoelectronic devices may be distinguished from those of QD optoelectronic devices fabricated using existing techniques, including Stranski-Krastanov (SK) growth, other lithographic techniques, and photoelectrochemical etching processes. In general, features such as the multilayer configuration of the present QDs as well as their monodispersity and high densities are distinguishing features of the present optoelectronic devices. In addition, by contrast to SK-grown devices in particular, the present fabrication processes do not lead to a wetting layer underneath the QDs. Thus, the present QD optoelectronic devices exhibit strong carrier confinement in all three dimensions by contrast to SK-grown devices in which carriers easily leak into the wetting layer underneath the QDs. Thus, the present QD optoelectronic devices may be characterized as being free of (i.e., do not comprise) a wetting layer. Another distinguishing feature of the present QD optoelectronic devices is the absence of oxygen (including oxides) therein, particularly within the electroluminescent, active layers of the devices. Thus, the present QD optoelectronic devices may be characterized as being free of (i.e., do not comprise) oxygen (or an oxide). The term “free” encompasses, but does not require, that the amount of oxygen/oxides be perfectly zero. The term “free” may be used to describe QD optoelectronic devices in which the amount of oxygen/oxides is no more than 10⁻¹⁷ cm⁻³. The lack of oxygen/oxides may be confirmed using Secondary Ion Mass Spectrometry.

### EXAMPLE

### Introduction

This Example presents an investigation of the structural and luminescence properties of InGaN/GaN QDs achieved through selective area epitaxy (SAE) on a block copolymer (BCP) patterned GaN template. The development of the pattern transfer process and SAE techniques allowed for the formation of ultra-high density QDs. The growth mechanism of nano-scale selective area epitaxy (NSAE) was examined, and the geometric properties of the QDs were characterized, revealing a nanopyramid QD structure with InGaN growth along the semi-polar plane, which can significantly reduce the non-uniformity in the layer thickness caused by the growth rate enhancement near mask opening. To assess the optical properties of the nanopyramid QDs, room temperature and low temperature photoluminescence (PL) measurements were conducted. The findings indicate a high internal quantum efficiency of over 60% for PL emission at approximately 490 nm. These results demonstrate the promising optical performance of the nanopyramid QDs achieved through SAE on BCP patterned GaN templates.

### Experimental

A schematic of the selective area growth of III-nitride QD on the BCP patterned template is shown in FIGS. 4A-4D. Specifically, after solvent cleaning, 20 nm SiNₓ was deposited on c-plane GaN on patterned sapphire substrates (PSS) by plasma enhanced chemical vapor deposition (PECVD). Then the templates were patterned by BCP lithography to form cylindrical nano-patterns, which were transferred into the underlying SiNₓ using CF₄ plasma by reactive ion etching (RIE). The polymer was removed by O₂ plasma and a piranha cleaning process, prior to the selective area growth. All the samples in this Example were grown by a MOCVD reactor using precursors including trimethyl indium (TMIn), triethyl gallium (TEGa) and NH₃, with purified N₂ and H₂ as carrier gases. Chamber pressure and NH₃ flow were fixed at 400 mbar and 6 slm, respectively, throughout the process. The growth temperature varied from 695° C. to 703° C. After the growth, some of the samples were dipped in buffered oxide etchants (BOE) for 1 min to remove the SiNₓ mask.

The morphology of SAE QDs was imaged using a Zeiss Gemini 450 field-emission scanning electron microscope (SEM), while the structural information was checked using FEI Titan 80-200 transmission electron microscopy (TEM). In addition, a Horiba LabRAM HR Evolution Raman spectrometer with a 405 nm laser was used to perform the room temperature (RT) and low temperature (LT) micro-photoluminescence (PL) characterizations on the samples. The laser spot had a diameter of 5 μm, which corresponded to 1-2×10⁴ QDs being excited by one excitation.

### Results and Discussion

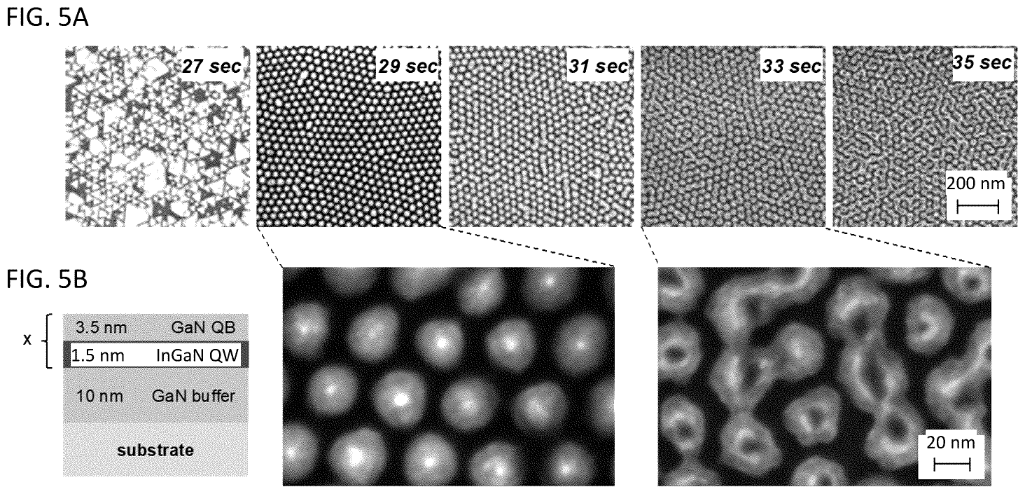

The pattern transfer process was first studied by adjusting the CF₄ RIE time ranging from 27 sec-35 sec with an increment of 2 sec, as shown in FIGS. 5A-5B. All five BCP patterned samples, along with a non-BCP patterned PSS substrate, were co-loaded into the reactor for growth. The epitaxial structure included a 10 nm GaN buffer; a 1.5-nm InGaN quantum well (QW); and a 3.5-nm GaN quantum barrier (QB). Layer thicknesses were calibrated on a planar substrate. In this Example, this structure is referred to as a InGaN/GaN QD.

As shown in the SEM images, random size nuclei were observed in the 27 sec sample, indicating incomplete breakthrough during pattern transfer. There was a thin SiNₓ layer left in the BCP pattern openings, which prevented the SAE of the (In) GaN material. As the RIE etching time increased to 29 sec-31 sec, the SiNₓ mask layer was fully etched in the openings, leading to isolated and faceted QD formation. Upon further increase in RIE time to 33 sec-35 sec, some of the adjacent openings started merging due to the SiNₓ over-etch. Therefore, a window of 29 sec-31 sec was demonstrated to be the optimized condition for pattern transfer and 31 sec was used as the RIE pattern transfer time in this Example. SEM images of each sample revealed consistently dense quantum dots (QDs) without signs of incomplete etching or merging of QDs, confirming the excellent reproducibility of the process.

The QD size and density were counted for the sample with 31 sec etching time using ImageJ software. As shown in FIGS. 6A-6B, the density of BCP patterned QDs in this Example was measured as 7-9×10¹⁰ cm⁻², which is much higher than QDs produced by existing lithographic techniques and self-assembly techniques. Note that the QD density by using the present method was much higher than the typical dislocation density of the GaN/sapphire template which ranges from 1×10⁹-1×10¹⁰ cm⁻², therefore largely reducing the dislocation penetrating through the QD active region. As shown in FIG. 6A, the average size of the QDs was 23.48 nm with a standard deviation of 2.38 nm, which is 6 nm larger than the BCP pattern dimension (17.22 nm). This can be attributed to both SiNₓ over-etching and lateral overgrowth of the QDs. Therefore, BCP patterning followed by SAE was demonstrated to be an effective method to achieve ultra-high density and uniform QDs.

To better understand the growth mechanism of the NSAE on a BCP lithographically defined surface, GaN-only QDs with different growth times of 300 sec, 600 sec, and 1000 sec were chosen, corresponding to 4.5 nm, 9 nm, and 15 nm on a planar template. As can be seen in FIGS. 7A-7C, the edge of the opening had a faster growth rate than the center due to reactive species surface diffusion. As growth continued, the GaN near the opening edge reached the top of the SiNₓ mask, at which point the material tended to merge toward to the center to eventually form a pyramid structure within each opening. Further introducing precursors into the reactor, the growth continued along the semi-polar {1 0 1̅ 1} planes with a reduced growth rate, resulting in high indium incorporation. Such semi-polar InGaN/GaN nanopyramid structures have desirable optical properties. To the inventors' knowledge, the semi-polar InGaN/GaN nanopyramid structures fabricated in this Example are believed to be the smallest ever reported. Moreover, the ability to achieve nanopyramid structures was unexpected in view of the challenges in nanometer scale selective epitaxial growth and its different growth mechanism as compared to micrometer scale selective epitaxial growth.

To confirm the geometry of the QD structure, TEM was performed on the 1× InGaN/GaN QD (FIG. 8). Prior to the characterization, 100 nm SiNₓ was deposited on top of the QD surface to prevent milling damage to the QDs during sample preparation and also to generate atomic contrast to the QDs. From the high-angle annular dark-field imaging (HAADF) image, it can be seen that the InGaN (lighter color) was deposited on the semi-polar planes of the nanopyramid structure, confirming the growth mechanism discussed above. Note that the InGaN/GaN contrast was not very clear for some of the QDs, which could be attributed to the QDs overlapping within the TEM sample volume, as well as the projection of the 3D features. The dimensions of the QDs were determined by averaging 5 different QDs, yielding an average height of 50 nm and an average width of 34 nm. Note that the size measured from TEM was larger than those from SEM images, which can be attributed to the contrast artifacts of the SEM scans. The growth rate at the early stage of the SAE was significantly (3-4 times) faster than on the planar structure. However, once the nanopyramid was fully complete, the growth rate along the semi-polar {1 0 1̅ 1} planes was reduced to 1.2-1.3 times that of the thin film growth rate.

The optical properties of the nanopyramid QDs were characterized by a μPL setup equipped with a 405 nm laser. To confirm that the emission peaks originated from QDs, samples grown at two different temperatures of 695° C. and 703° C. were fabricated and compared. As shown in FIG. 9A, the peak PL emission wavelengths from the planar structures were measured to be 466 nm and 456 nm respectively, with an expected blue shift at higher temperature due to the lower indium incorporation rate. As shown in FIG. 9B, for the QD structures, longer peak wavelengths of 514 nm and 488 nm were observed as compared to the planar structure. This was probably due to the combined effect of higher indium incorporation on the semi-polar plane and a thicker InGaN layer, even though larger quantum confinement and a reduced polarization field tend to blue shift the emission spectra. Like the planar sample, the wavelength shifted to a shorter regime as growth temperature increased for the BCP patterned samples. This was because of the lower indium incorporation rate at higher growth temperature, indicating the 2=488 nm and 2=514 nm peaks were from QD emission. A broad peak centered around 610 nm can be attributed to the surface-defect related emission, which was pronounced after SiNₓ dielectric mask removal, as shown in FIG. 10A.

To enhance emission intensity, additional periods of InGaN/GaN active layers were grown within the QDs. FIG. 10B plots the PL spectra from 1-3× InGaN/GaN QDs. The wavelength from three samples remained the same while the intensity increased significantly as the number of InGaN layers increased, which indicates the stable growth rate along semi-polar {1 0 1̅ 1} planes after the formation of the nanopyramid. The broad defect peak was kept at the same level due to the similar exposed surface area from three samples. The FWHM was measured as 68 nm (351 meV), which was larger than that from a planar structure at a similar wavelength (19 nm or 103 meV). This could be attributed to non-uniform indium incorporation from the pyramid top to bottom, or thickness variation.

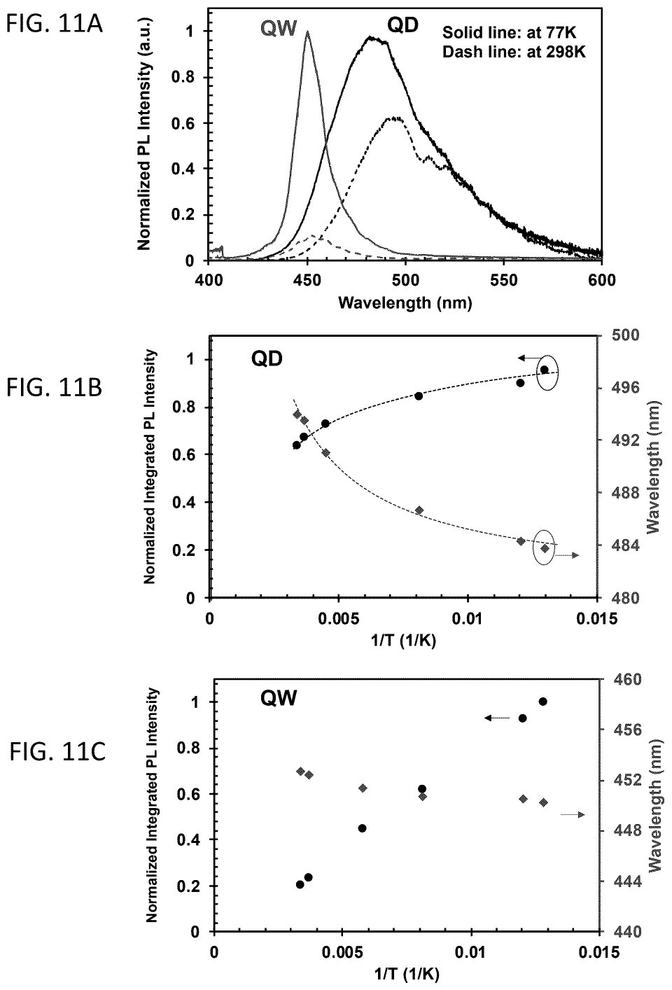

Temperature PL measurements were performed on the 3× InGaN/GaN QDs and plotted in FIGS. 11A-11C. The FWHM from the QD sample collected after subtracting the broad defect peak decreased from 68 nm (351 meV) to 56 nm (303 meV) because of the reduced thermal broadening. Besides, the emission wavelength showed a 11.43 nm blue shift as temperature decreased from 300 K to 77K, which was much larger than that from the planar structure (2.46 nm). The blue shift from QD can be described by the expression E(T)=E(0)−αT²/(T+β), where E(0) represents the bandgap at zero temperature and α and β are Varshni's fitting parameter. The dash line in FIG. 11B is the fitting curve based on Varshni's model with E(0)=2.58 eV, α=0.24 meV/K, β=4.13×10⁻⁴ K, which corresponds well with the measured results. The extracted values were slightly smaller than the ones from micro-sized pyramid structures, which could be attributed to several factors, such as different excitation power and energy, different wavelength regime, or potential multiple emission peaks. By contrast, the temperature dependent emission wavelengths from the planar QW structure showed an “S” shaped trend. This was due to the large internal electric field and carrier localization in the InGaN. The PL spectra at low temperature (77 K) as well as room temperature (298 K) for both QW and QDs were compared and plotted in FIG. 11A. Nanopyramid QD structures showed a large integrated PL intensity ratio I_{RT}/I_{77K} of 0.667 as compared to that from the QW structure, which was 0.203, attributed to the better carrier confinement of the QDs. In order to estimate the internal quantum efficiency, an Arrhenius equation

$$I ( T ) = \frac{{I}_{0}}{1 + {A}_{1} exp ( \frac{{E}_{1}}{kT} ) + {A}_{2} exp ( \frac{{E}_{2}}{kT} )}$$

was used to fit the temperature dependent integrated intensity plot, as shown in FIG. 11B. E₁ and E₂ were fitted as 17 meV and 100.2 meV, while A₁ and A₂ were fitted as 0.84 and 6.55. E₁ of 17 meV is known to be associated with thermal escape energy for carriers captured by the nonradiative centers, while A₁ indicates the density of the nonradiative centers. The low A₁ value was the main contributor to the high IQE observed, which was estimated to be ˜63% based on the ratio of I_{RT}/I₀. Note that all the emission spectra were collected on the QD sample even without a capping layer, indicating the emission properties from the nanopyramid QDs are very encouraging.

### Summary and Conclusions

Visible emission of 488 nm and 514 nm from ultra-high density InGaN/GaN nanopyramid QDs defined by BCP lithography and MOCVD NSAE were demonstrated. It was shown that the InGaN layer growth occurred along the semi-polar {1 0 1̅ 1} planes after the completion of the nanopyramid formation. As high as 63.52% internal quantum efficiency was achieved, as estimated from variable temperature PL measurements. PL FWHM from the QD emission reduced from 68 nm (353 meV) to 56 nm (303 meV) as temperature reduced to 77K. Further optimization of the QD layered structure and nanoscale MOCVD selective area growth (e.g., growth pressure, V/III ratio, and growth rate) may be used to achieve even narrower linewidth and higher intensity QD emission.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more.”

The foregoing description of illustrative embodiments of the disclosure has been presented for purposes of illustration and of description. It is not intended to be exhaustive or to limit the disclosure to the precise form disclosed, and modifications and variations are possible in light of the above teachings or may be acquired from practice of the disclosure. The embodiments were chosen and described in order to explain the principles of the disclosure and as practical applications of the disclosure to enable one skilled in the art to utilize the disclosure in various embodiments and with various modifications as suited to the particular use contemplated. It is intended that the scope of the disclosure be defined by the claims appended hereto and their equivalents.

If not already included, all numeric values of parameters in the present disclosure are proceeded by the term “about” which means approximately. This encompasses those variations inherent to the measurement of the relevant parameter as understood by those of ordinary skill in the art. This also encompasses the exact value of the disclosed numeric value and values that round to the disclosed numeric value.

What is claimed is:

1. A method for fabricating a quantum dot optoelectronic device, the method comprising:
(a) forming a patterned mask layer on a base structure, the patterned mask layer having a plurality of openings defined therein, the base structure comprising a multilayer stack and an etch stop layer below the multilayer stack, the multilayer stack comprising a III-V semiconductor quantum well layer between III-V semiconductor quantum barrier layers;
(b) selectively growing, via metalorganic vapor phase epitaxy (MOVPE), a plurality of etch mask layers in respective openings of the plurality of openings of the patterned mask layer; and
(c) selectively removing, via in situ etching, material of the base structure not protected by each etch mask layer of the plurality of etch mask layers until the etch stop layer is exposed and a plurality of quantum is formed in the base structure, each quantum dot comprising the multilayer stack and a respective etch mask layer over the multilayer stack.

2. The method of claim 1, further comprising forming a cap layer on the plurality of quantum dots.

3. The method of claim 1, wherein each etch mask layer of the plurality of etch mask layers is grown as a nanopyramid etch mask layer.

4. The method of claim 1, wherein the base structure further comprises a release layer between the patterned mask layer and the multilayer stack, the method further comprising:
(d) removing, via in situ etching, material of the release layer exposed through each opening of the plurality of openings of the patterned mask layer until the multilayer stack is exposed, thereby forming an etched release layer; and
(e) removing, via in situ etching, the etched release layer and the patterned mask layer.

5. The method of claim 4, wherein the plurality of etch mask layers are grown on exposed portions of the multilayer stack.

6. The method of claim 1, wherein the III-V semiconductor quantum well layer is a III-N semiconductor quantum well layer and the III-V semiconductor quantum barrier layers are III-N semiconductor quantum barrier layers.

7. The method of claim 1, wherein multilayer stack comprises multiple III-V quantum well layers and each quantum dot of the plurality of quantum dots comprises the multiple III-V quantum well layers.

8. The method of claim 1, wherein the plurality of quantum dots is characterized by a monomodal size distribution having a standard deviation of no more than 12% of an average of the monomodal size distribution and the plurality of quantum dots is further characterized by a density of at least 5×10¹⁰ cm⁻².

9. The method of claim 1, wherein an active layer comprising the plurality of quantum dots is free of oxygen or an oxide.

10. A method for fabricating a quantum dot optoelectronic device, the method comprising:
(a) forming a patterned mask layer on a base structure, the patterned mask layer having a plurality of openings defined therein, the base structure comprising an etch stop layer and a release layer between the patterned mask layer and etch stop layer;
(b) removing, via in situ etching, material of the release layer exposed through each opening of the plurality of openings of the patterned mask layer until the etch stop layer is exposed, thereby forming an etched release layer;
(c) selectively growing, via MOVPE a plurality of quantum dots in respective openings of the plurality of openings of the patterned mask layer and the etched release layer, each quantum dot comprising a III-V semiconductor quantum well layer between III-V semiconductor quantum barrier layers;
(d) selectively growing, via MOVPE, a plurality of etch mask layers on respective quantum dots in respective openings of the plurality of openings of the patterned mask layer and the etched release layer; and
(e) removing, via in situ etching, the etched release layer and the patterned mask layer.

11. The method of claim 10, wherein each quantum dot of the plurality of quantum dots is grown as a nanopyramid quantum dot.

12. The method of claim 10, further comprising forming a cap layer on the plurality of quantum dots.

13. A method for fabricating a quantum dot optoelectronic device, the method comprising:
(a) forming a patterned mask layer on a base structure, the patterned mask layer having a plurality of openings defined therein;
(b) selectively growing, via MOVPE, a plurality of nanopyramid quantum dots in respective openings of the plurality of openings of the patterned mask layer, each nanopyramid quantum dot comprising a III-V semiconductor quantum well layer between III-V semiconductor quantum barrier layers; and
(c) removing the patterned mask layer.

14. The method of claim 13, wherein a surface of the base structure on which the plurality of the nanopyramid quantum dots is grown is a c-plane surface.

15. The method of claim 13, further comprising forming a cap layer on the plurality of quantum dots.

16. The method of claim 13, further comprising (d) removing, via in situ etching, material of the base structure exposed through each opening of the plurality of openings of the patterned mask layer to deepen each opening.

17. A quantum dot optoelectronic device comprising:
a base structure; and
an active layer on the base structure, the active layer comprising a plurality of quantum dots, each quantum dot comprising a III-V semiconductor quantum well layer between III-V semiconductor quantum barrier layers, wherein each quantum dot has a nanopyramid shape, each quantum dot is between an underlying etch stop layer and overlying etch mask layers, or both.

18. The quantum dot optoelectronic device of claim 17, wherein each quantum dot is a nanopyramid quantum dot.

19. The quantum dot optoelectronic device of claim 17, wherein each quantum dot is between the underlying etch stop layer and the overlying etch mask layers.

20. The quantum dot optoelectronic device of claim 19, wherein each quantum dot is a nanopyramid quantum dot.
